(19) United States
(12) Patent Application Publication
(10) Pub. No.: US 2007/0155166 A1
(43) Pub. Date: Jul. 5, 2007

(54) METHOD AND APPARATUS FOR DEPOSITING COPPER WIRING

(76) Inventor: Jong-Guk Kim, Seoul (KR)

Correspondence Address: SHERR & NOURSE, PLLC, 620 HERNDON PARKWAY, SUITE 200, HERNDON, VA, 20170, US

(21) Appl. No.: 11/559,630

(22) Filed: Nov. 14, 2006

(30) Foreign Application Priority Data
Dec. 14, 2005 (KR) 10-2005-0123533

(51) Int. Cl. H01L 21/4763

(52) U.S. Cl. 438/629

(57) ABSTRACT

A method of depositing copper wiring that includes at least one of the following. Transporting a semiconductor substrate with a damascene pattern into a first chamber. Substantially concurrently performing a degassing process and a process of removing a Copper Oxide film on a semiconductor substrate located in a first chamber.

The present application claims priority under 35 U.S.C. 119 and 35 U.S.C. 365 to Korean Patent Application No. 10-2005-0123533 (filed on Dec. 14, 2005), which is hereby incorporated by reference in its entirety.

### BACKGROUND

As design rules of semiconductor devices are curtailed, a line width of wiring may become narrower. Single damascene processes or a dual damascene processes may be used to form wiring, which may use Copper having a lower resistance (Rs).

A dual damascene process may be a process in which an insulating film is formed over a semiconductor substrate and etched. An insulating film may be etched using a via first scheme or a trench first scheme to form a dual damascene pattern. A barrier film may be deposited over a dual damascene pattern. Copper may be deposited to form a Copper film which fills a dual damascene pattern. A Copper film may be planarized (e.g. by using chemical mechanical polishing (CMP)) to form copper wiring.

After a dual damascene pattern is formed in an insulating film of a semiconductor substrate, the semiconductor substrate may be placed in a first chamber. In a first chamber, gases in a semiconductor substrate may be discharged (i.e. degassed). An internal temperature of a first chamber may be raised to reach about 350° C.

If there is a leak in a first chamber during discharge of gasses, Oxygen in the air may enter into the first chamber. If oxygen enters into a first chamber, the Oxygen may react with a lower Copper wiring, which may be exposed by a dual damascene pattern, to form a Copper Oxide film on a surface of the lower Copper wiring. In order to remove a Copper Oxide film, a semiconductor substrate may be placed in a second chamber. In a second chamber, hydrogen (H₂) plasma may be used in a vacuum (e.g. at room temperature) to remove the Copper Oxide (CuOₓ) film.

After a Copper Oxide film is removed, a semiconductor substrate may be placed in a third chamber where a barrier film is deposited over a damascene pattern. In a fourth chamber, a Copper seed layer may be deposited over a barrier film. A Copper film may be deposited to gap-fill a damascene pattern.

It may be possible that a Copper Oxide film is not completely removed. If a Copper Oxide film is not completely removed, device failure may result.

### SUMMARY

Embodiments relate to forming Copper wiring in a semiconductor substrate using a damascene process. Embodiments relate to depositing Copper wiring in a manner that substantially prevents device failure due to Copper Oxide films. Embodiments relate to an apparatus which deposits copper wiring in an effective manner.

Embodiments relate to a method of depositing Copper wiring, which may comprise at least one of the following steps: A step of placing a semiconductor substrate with a damascene pattern in a first chamber. A step of substantially concurrently performing a degassing process on a semiconductor substrate and a process of removing a Copper Oxide film on the semiconductor substrate located in a first chamber. A step of transferring a semiconductor substrate from a first chamber to a second chamber. A step of depositing a barrier film over a semiconductor substrate in a second chamber. A step of transferring a semiconductor substrate with a barrier film in a third chamber. A step of depositing a Copper seed layer over a semiconductor substrate having a barrier film.

Embodiments relate to a depositing apparatus, which may include at least one of the following: A first chamber which substantially concurrently performs a degassing process and a process of removing a Copper Oxide film. A second chamber which deposits a barrier film. A third chamber which deposits a Copper seed layer. A substrate transfer unit which transfers a semiconductor substrate into a first chamber, a second chamber, and/or a third chamber.

In embodiments, a depositing apparatus may include at least one of the following: A chamber that substantially concurrently performs a degassing process and a process of removing a Copper Oxide film. A Hydrogen gas feeding unit connected to a chamber which selectively feeds Hydrogen gas into the chamber based on the degree of vacuum inside the chamber.

### BRIEF DESCRIPTION OF THE DRAWINGS

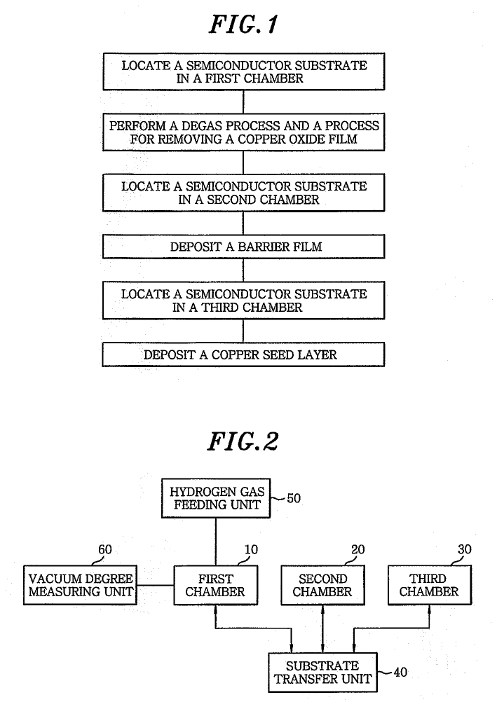

Example FIG. 1 is a process block diagram illustrating a method of depositing Copper wiring, in accordance with embodiments.

Example FIG. 2 is a block diagram illustrating an apparatus which deposits Copper wiring, in accordance with embodiments.

### DETAILED DESCRIPTION

Example FIG. 1 illustrates a process block diagram of a method of depositing Copper wiring, in accordance with embodiments. Example FIG. 2 is a block diagram illustrating an apparatus that deposits Copper wiring, in accordance with embodiments. In embodiments, a degassing process and a process of removing a Copper Oxide film are substantially concurrently performed in the same chamber.

As illustrated in FIG. 2, an apparatus of depositing Copper wiring has three or six chambers, in accordance with embodiments. In embodiments with an apparatus having six chambers, there may be two substantially identical sets of three chambers. Embodiments with an apparatus having three chambers are illustrated in FIG. 2. However, embodiments with an apparatus having six chambers can be realized by the three chambers illustrated in FIG. 2 as one of the two sets of three chambers.

The apparatus which deposits Copper wiring, in accordance with embodiments, may include first chamber 10, second chamber 20, third chamber 30, and/or substrate transfer unit 40. Substrate transfer unit 40 may transfer semiconductor substrates to first chamber 10, second chamber 20, and/or third chamber 30.

First chamber 10 may substantially concurrently perform a degas process and a process that removes a Copper Oxide film. First chamber 10 may be connected to a vacuum pump which may evaporate air inside of first chamber 10. First chamber 10 may be connected to Hydrogen gas feeding unit 50, which may feed Hydrogen gas to first chamber 10.

First chamber 10 may be coupled to vacuum degree measuring unit 60, which may measure the degree of vacuum inside of first chamber 10. Hydrogen gas feeding unit 50 may feed Hydrogen gas into first chamber 10 if there is an external leak in first chamber 10 which may cause external air to flow into first chamber 10. If external air flows into first chamber 10, the degree of vacuum may be degraded. Degradation of the degree of vacuum may be measured by vacuum degree measuring unit 60. Second chamber 20 may deposit a barrier film. Third chamber 30 may deposit a copper seed layer.

After a damascene pattern is formed in an insulating layer of a semiconductor substrate, the semiconductor substrate may be moved into first chamber 10. Inside first chamber 10, Copper wiring may be formed in a damascene pattern, in accordance with embodiments. A vacuum process may be performed in first chamber 10 to produce a vacuum state. The internal temperature of first chamber 10 may be raised to about 350° C. A degassing process which discharges and/or removes gases from a semiconductor substrate may be performed.

If an external leak causes an external air to flow into first chamber 10 during a degassing process, vacuum degree measuring unit 60 may detect the degree that a vacuum state is degraded due to inflow of external air, in accordance with embodiments. If it is detected that the degree of vacuum is degraded below a predetermined threshold, Hydrogen gas feeding unit 50 may feed Hydrogen gas into first chamber 10. In embodiments, feeding Hydrogen gas into first chamber 10 may prevent a Copper Oxide film from forming on surfaces of a lower Copper wiring. In embodiments, feeding Hydrogen gas into first chamber 10 may remove a Copper Oxide film formed on a lower Copper wiring.

In embodiments, Hydrogen gas feeding unit 50 may feed Hydrogen gas into first chamber 10 during a degassing process regardless of whether the external leak is generated or detected. In embodiments, feeding Hydrogen by Hydrogen gas feed unit 50 may substantially prevent formation of a Copper Oxide film.

In embodiments, when processes of first chamber 10 are completed, substrate transfer unit 40 may transfers a semiconductor substrate to second chamber 20. In second chamber 20, a barrier film may be deposited, in accordance with embodiments. In embodiments, depositing a barrier film may include depositing Tantalum Nitride (TaN) and/or Tantalum (Ta). In embodiments, after depositing a barrier film, substrate transfer unit 40 may transfer a semiconductor substrate to third chamber 30, in which a Copper seed layer may be deposited.

In embodiments, since a degas process and a process of removing a Copper Oxide film are performed substantially concurrently in a single chamber (e.g. first chamber 10), a process of depositing copper wiring may be simplified.

In embodiments, substantial prevention of formation of a copper oxide film on a lower copper wiring, increases in resistance (e.g. due to a Copper Oxide film) may be prevented. In embodiments, removal of a copper oxide film formed on a lower copper wiring, increases in resistance (e.g. due to a Copper Oxide film) may be prevented. Prevention of increases in resistance may prevent device failure, according to embodiments.

It will be apparent to those skilled in the art that various modifications and variations can be made to embodiments. Thus, it is intended that embodiments cover modifications and variations thereof within the scope of the appended claims.

What is claimed is:

1. A method comprising:
transferring a semiconductor substrate with a damascene pattern into a first chamber; and
substantially concurrently performing a degassing process and a process of removing a Copper Oxide film from the semiconductor substrate in the first chamber.

2. The method of claim 1, comprising:
transferring the semiconductor substrate from the first chamber to a second chamber; and
depositing a barrier film on the semiconductor substrate in the second chamber.

3. The method of claim 2, comprising:
transferring the semiconductor substrate with the barrier film to a third chamber; and
depositing a Copper seed layer on the semiconductor substrate with the barrier film.

4. The method of claim 1, comprising:
maintaining a vacuum state in the first chamber during the degassing process; and
raising the internal temperature of the first chamber during the degassing process.

5. The method of claim 1, wherein the process of removing the Copper Oxide film is performed by feeding Hydrogen gas into the first chamber.

6. The method of claim 1, comprising:
measuring a degree of vacuum in the first chamber;
if the degree of vacuum is below a predetermined threshold, feeding the Hydrogen gas into the first chamber.

7. The method of claim 6, wherein the Hydrogen gas is fed into the first chamber when the degree of vacuum is degraded due to an inflow of oxygen from outside the first chamber.

8. The method of claim 1, wherein am internal temperature of the first chamber is raised to about 350° C. during the degas process.

9. An apparatus comprising a first chamber which is configured to substantially concurrently perform:
a degassing process on a semiconductor substrate; and
a process of removing a Copper Oxide film from a semiconductor substrate.

10. The apparatus of claim 9, wherein the apparatus is configured to deposit Copper wiring.

11. The apparatus of claim 9, comprising a second chamber configured to deposit a barrier film.

12. The apparatus of claim 9, comprising a third chamber configured to deposit a Copper seed layer.

13. The apparatus of claim 9, comprising a substrate transfer unit configured to transfer the semiconductor substrate into at least one of:
the first chamber;
a second chamber configured to deposit a barrier film; and
a third chamber configured to deposit a Copper seed layer.

14. The apparatus of claim 9, wherein the first chamber is connected to a Hydrogen gas feeding unit which is configured to feed Hydrogen gas into the first chamber.

15. The apparatus of claim 14, wherein the Hydrogen gas feeding unit is configured to substantially prevent a Copper Oxide film from being formed on a lower Copper wiring of the semiconductor substrate.

16. The apparatus of claim 14, wherein the first chamber is coupled to a vacuum degree measuring unit which is configured to measure the degree of vacuum inside the first chamber.

17. The apparatus of claim 16, wherein the Hydrogen gas feeding unit is configured to feed Hydrogen gas into the first chamber only if the degree of vacuum measured by the vacuum degree measuring unit is below a predetermined threshold.

18. An apparatus comprising a chamber, wherein the chamber is configured to substantially concurrently perform:
a degassing process on a semiconductor substrate; and
a process of removing a Copper Oxide film from the semiconductor substrate.

19. The apparatus of claim 18, comprising a Hydrogen gas feeding unit connected to the chamber, wherein the Hydrogen gas feeding unit is configured to selectively feed Hydrogen gas into the chamber based on a degree of vacuum inside of the chamber.

20. The apparatus of claim 18, wherein the apparatus if configured to deposit Copper wiring over the semiconductor substrate.
